(19) United States
(12) Patent Application Publication
(10) Pub. No.: US 2023/0110795 A1
(43) Pub. Date: Apr. 13, 2023

(54) INTEGRATED CIRCUIT AND ELECTRONIC DEVICE

(71) Applicant: XIAMEN INDUSTRIAL TECHNOLOGY RESEARCH INSTITUTE CO., LTD., Xiamen, Fujian (CN)

(72) Inventors: Ting Ying SHEN, Xiamen (CN); Qi XIANG, Xiamen (CN)

(73) Assignee: XIAMEN INDUSTRIAL TECHNOLOGY RESEARCH INSTITUTE CO., LTD., Xiamen, Fujian (CN)

(21) Appl. No.: 17/796,166

(22) PCT Filed: Nov. 27, 2020
(86) PCT No.: PCT/CN2020/132019

§ 371 Date: Jul. 28, 2022

(30) Foreign Application Priority Data
Nov. 28, 2019 (CN) 201911189486.7

(51) Int. Cl. H01L 23/528; H10B 63/00

(52) U.S. Cl. CPC H01L 23/5283; H01L 27/2463

(57) ABSTRACT

An integrated circuit and an electronic device, and provides an integrated circuit having better area efficiency. The integrated circuit may be a resistive random access memory, which includes a plurality of resistive memory cells arranged in row and column directions; each resistive memory cell includes a resistive switching unit and a switch unit coupled to the resistive switching unit; the resistive switching units in the column direction are respectively coupled to corresponding source lines; the source lines include first source lines and second source lines; and the first source lines and the second source lines are located on different interconnect layers.

### TECHNICAL FIELD

The present invention relates to an integrated circuit, and in particular, to an integrated circuit and an electronic device.

### BACKGROUND

In the field of integrated circuits, the integrated circuits are becoming smaller and more compact. More electronic components can be formed and arranged in a given area so that a device may be made smaller, i.e., the device may include smaller storage units and interconnects for operating the storage units. However, the close arrangement of the electronic components may lead to undesired effects. Therefore, it is necessary to provide a design of an integrated circuit that is more efficient in utilization of available space.

A Resistive Random Access Memory (RRAM) is a new technology. The RRAM combines the advantages of a Static Random Access Memory (SRAM), a Dynamic Random Access Memory (DRAM), and a flash, and therefore can achieve the characteristics of non-volatility, ultra-high density, low power consumption, low cost, and high scalability, and is considered as a promising candidate for the next generation of Non-Volatile Memory (NVM) in the industry. Due to its relatively large bandwidth and rapidly increasing capacity, the emerging NVM can play a crucial role in the integrated storage and computing technology of Artificial Intelligence (AI) chips.

A basic structure of a typical RRAM consists of a bottom electrode, a resistive switching layer, and a top electrode to form a Metal-Insulator-Metal (MIM) stack structure, and the resistive switching layer serves as a medium for ion transport and storage. Among various resistance change principle models of the RRAM, the most widely accepted is a conductive filament model, i.e., dendritic conductive filaments are formed in an insulating dielectric film. The set (1 indicating a change process from high resistance to low resistance) and reset (0 indicating a change process from low resistance to high resistance) of a memory cause the connection or breakage of conductive filaments, resulting in resistance change of a thin film between low resistance and high resistance to form data storage of a logic “0” data bit or a logic “1” data bit.

FIG. 1 is a plan view showing a part of the structure of the RRAM. In such a bipolar type, resistive switching units in the same column corresponding to bit lines share corresponding source lines, and the bit lines and the source lines are symmetrical to each other and can be exchanged.

However, in such a memory array structure, since a dedicated source line is configured for each bit line, in the formation of a memory having a high integration density, source lines become an obstacle to the size reduction of a memory array in the width direction of an active area (AA) or diffusion, and the increase of the integration density of the RRAM will thus be affected.

The present invention aims to provide an integrated circuit having high area efficiency.

### SUMMARY

The present invention provides an integrated circuit, including a plurality of integrated circuit units and a plurality of source lines, where the plurality of source lines include first source lines and second source lines located on different layers, the first source lines and the second source lines are located on different interconnect layers, and the integrated circuit units are coupled to the first source lines or the second source lines.

The present invention further provides a memory, including a plurality of storage units and a plurality of source lines, where the plurality of source lines include first source lines and second source lines located on different layers, the first source lines and the second source lines are located on different interconnect layers, the storage units are coupled to the first source lines or the second source lines, and the first source lines and the second source lines, of which the projections at least partially overlap with each other in the vertical direction, are respectively coupled to the storage units located on different sides of the first source lines and the second source lines.

The present invention further provides a Resistive Random Access Memory (RRAM), where the RRAM includes a plurality of resistive memory cells arranged in row and column directions, and the resistive memory cells each includes a resistive switching unit and a switch unit coupled to the resistive switching unit; the source lines include first source lines and second source lines, and the first source lines and the second source lines are located on different interconnect layers;
the first source lines are located on a first interconnect layer, and the second source lines are located on a second interconnect layer above the first interconnect layer;
the first source lines and the second source lines are respectively coupled to resistive switching units on different sides;
the first source lines and the second source lines are located between two adjacent columns of resistive switching units, and the projection of at least one of the first source lines at least partially overlaps the projection of the corresponding second source line in the vertical direction; all the source lines are perpendicular to word lines in the spatial direction, and all the source lines are parallel to bit lines in the spatial direction; the bit lines are located on a third interconnect layer above the second interconnect layer; and
the first source lines are electrically connected to a substrate through N groups of contact plugs and N-1 groups of bottom connecting platforms, and the second source lines are electrically connected to the substrate through M groups of contact plugs and M-1 groups of bottom connecting platforms, where M is greater than N.

The resistive switching unit may be one or more of an RRAM, an MRAM, an FRAM, or a PRAM.

According to the present invention, the RRAM can achieve the following effect: the source lines include the first source lines and the second source lines, and the second source lines are located above the first source lines in a vertical space, such that the distance between the resistive switching units can be reduced, thereby improving area efficiency of a memory array, compared with the prior art in which source lines are located on the same side of resistive switching units.

### BRIEF DESCRIPTION OF THE DRAWINGS

FIG. 1 is a plan view of part of the structure of a resistive random access memory. FIG. 2 is a plan view of part of the structure of a resistive random access memory in accordance with an embodiment of the present invention. FIG. 3A is a cross-sectional view of a resistive random access memory in the direction of A-A′ in accordance with an embodiment of the present invention.

FIG. 3B is a cross-sectional view of a resistive random access memory in the direction of B-B′ in accordance with an embodiment of the present invention.

FIG. 3C is a cross-sectional view of a resistive random access memory in the direction of C-C′ in accordance with an embodiment of the present invention.

FIG. 3D is a cross-sectional view of a resistive random access memory in the direction of D-D′ in accordance with an embodiment of the present invention.

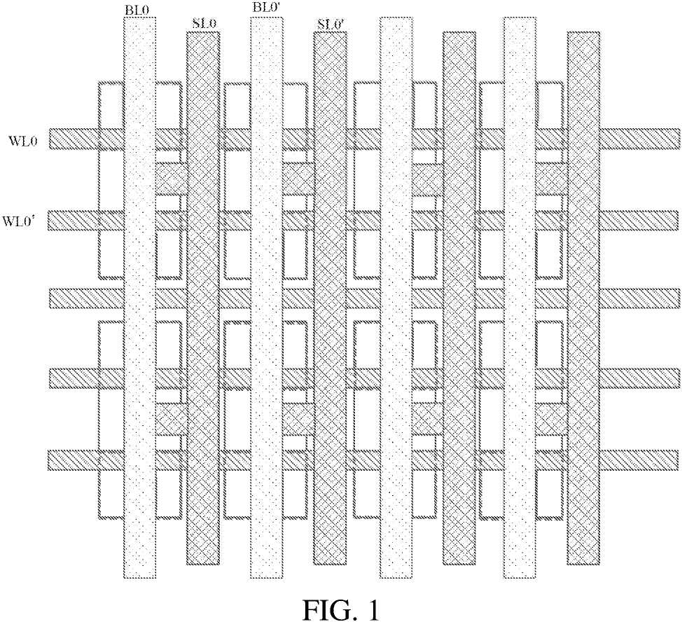

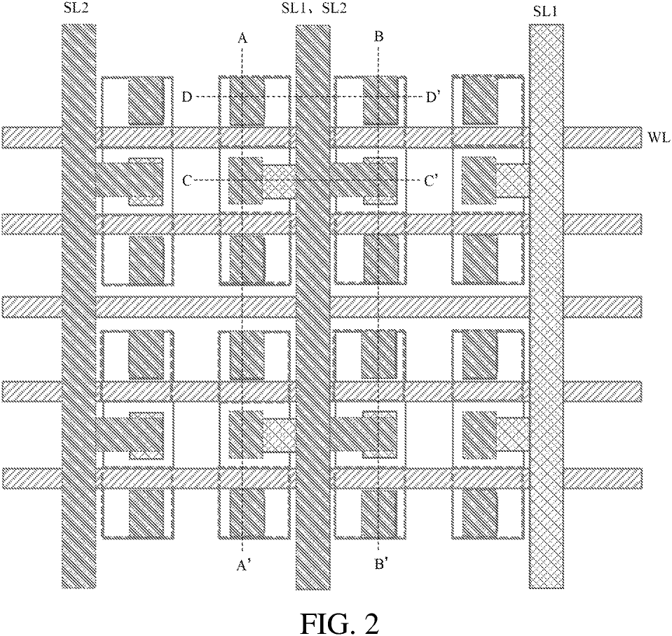

### REFERENCE NUMERALS

100: substrate
101, 102, 103, 104, 105: insulating layer
108, 109, 110, 111, 120, 208, 209, 210, 211, 220, 222: contact plug
112(M1), 113(M2), 212(M1), 213(M2): bottom connecting platform
106, 107, 206, 207: resistive switching unit
SL0, SL0′, SL1, SL2: source line
WL0, WL0′, WL1, WL2: word line
BL0, BL0′, BL: bit line

### DETAILED DESCRIPTION

To make the objectives, features, and advantages of the present invention clearer and easier to understand, the following describes the technical solutions in embodiments of the present invention clearly and completely in conjunction with the accompanying drawings in the embodiments of the present invention. Apparently, the described embodiments are merely some of the embodiments of the present invention, not all of the embodiments. On the basis of the embodiments in the present invention, all other embodiments obtained by a person skilled in the art without inventive efforts shall fall within the scope of protection of the present invention.

An embodiment of the present invention provides an integrated circuit, including a plurality of integrated circuit units and a plurality of source lines, where the plurality of source lines include first source lines and second source lines located on different layers, the first source lines and the second source lines are located on different interconnect layers, and the integrated circuit units are coupled to the first source lines or the second source lines.

The first source lines are located on a first interconnect layer, and the second source lines are located on a second interconnect layer above the first interconnect layer.

Another embodiment of the present invention provides a memory, including a plurality of storage units and a plurality of source lines, where the plurality of source lines include first source lines and second source lines located on different layers, the first source lines and the second source lines are located on different interconnect layers, and the storage units are coupled to the first source lines or the second source lines.

The first source lines are located on a first interconnect layer, and the second source lines are located on a second interconnect layer above the first interconnect layer; and the first source lines and the second source lines, of which the projections at least partially overlap with each other in the vertical direction, are respectively coupled to the storage units located on different sides of the first source lines and the second source lines.

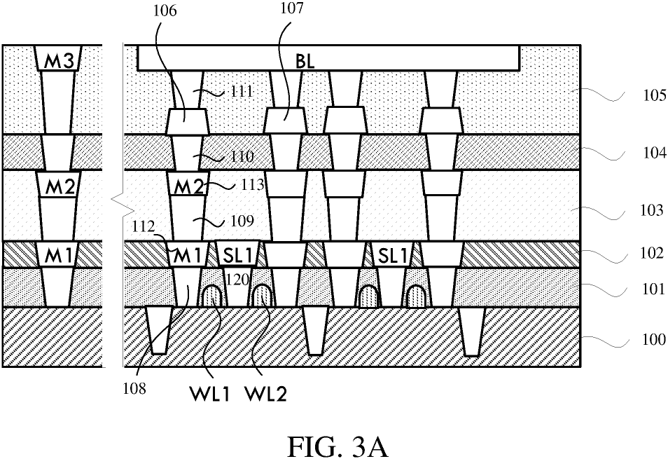

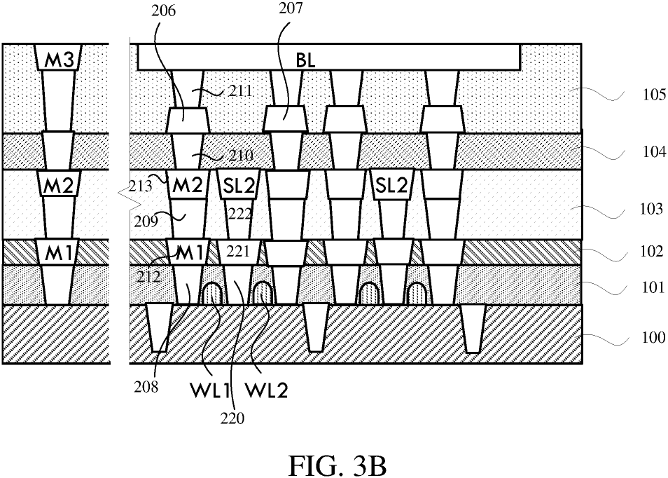

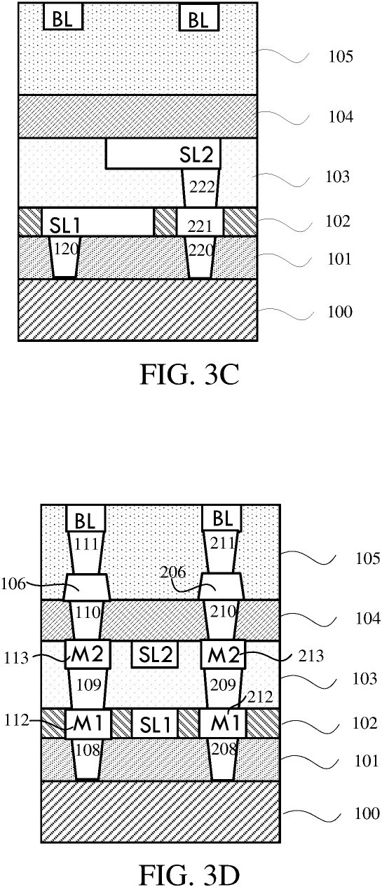

Another embodiment of the present invention provides a resistive random access memory. FIG. 2 is a plan view of part of the structure of a resistive random access memory in accordance with an embodiment of the present invention. FIG. 3A is a cross-sectional view along section line A-A′ in FIG. 2. FIG. 3B is a cross-sectional view along section line B-B′ in FIG. 2. FIG. 3C is a cross-sectional view along section line C-C′ in FIG. 2. FIG. 3D is a cross-sectional view along section line D-D′ in FIG. 2.

FIG. 2 is a schematic plan view of part of the structure of a resistive random access memory in accordance with an embodiment of the present invention. A memory array has a multi-layer wiring structure on a silicon substrate. In this embodiment, metal layers and control gates are provided on the substrate. The control gate may be one of a high K metal gate, a Fin Field Effect Transistor (FiNFET), or a conductive polysilicon layer. Bit lines (BLs) are formed in the direction orthogonal to word lines (WLs). In order to more clearly show the positions of source lines and resistive switching units, the BLs are not shown in FIG. 2. The BLs are located in a third interconnect layer above a second interconnect layer. The BLs are made of metal such as aluminum (Al) or copper (Cu).

Source lines SL1/SL2 are formed parallel to the BLs in the spatial direction, and the source lines SL1/SL2 are perpendicular to the WLs in the spatial direction. In this embodiment, the source lines SL1 are located in a first interconnect layer and are arranged through the same metal layer 1 (M1) as bottom connecting platforms 112. The source lines SL2 are located in the second interconnect layer and are arranged through the same metal layer (M2) as bottom connecting platforms 113. The resistive switching units are located on an insulating layer between the second interconnect layer and the third interconnect layer.

The resistive switching unit in this embodiment may be any one or a combination of several of a Resistive Random Access Memory (RRAM), a Magnetic Random Access Memory (MRAM), a Ferroelectric Random Access Memory (FRAM), or a Phase-Change Random Access Memory (PRAM).

FIG. 3A, FIG. 3B, FIG. 3C, and FIG. 3D show cross-sectional views of a region of an array shown in FIG. 2 along section lines A-A′, B-B′, C-C′, D-D′, respectively.

In FIG. 3A, for example, an insulating layer 101 is formed on a surface of a substrate 100 to define an active area of an access transistor, and the insulating layer 101 is made of a silicon oxide film or the like. On the substrate 100, the source lines SL1 are located on an insulating layer 102, are arranged through the metal layer 1 (M1), and are coupled to the columns where resistive switching units 106 are located. The metal layer 1 may be made of metal such as Al or Cu. The source lines SL1 are perpendicular to the WLs in the spatial direction and parallel to the BLs in the spatial direction. Shown in the figure are connection portions between the source lines SL1 and contact plugs, and therefore, the spatial relationships cannot be directly observed. Contact holes are formed in the interlayer insulating layer 101, contact plugs 120 are formed, and the source lines SL1 are electrically connected to the surface of the substrate 100 through the contact plugs 120. The resistive switching units 106 are formed on the insulating layer 104 and are connected to the metal layer 2 through contact plugs 110 on the insulating layer 104. The BLs are arranged through the metal layer 3 (M3), and are connected to the resistive switching units 106 through the contact plugs 111.

As shown in FIG. 3B, the insulating area 101 is formed on the surface of the substrate 100 to define the active area of the access transistor. On the substrate 100, the source lines SL2 are arranged through the metal layer 2 (M2) located above the metal layer 1 (M1), and the source lines SL2 are coupled to the columns where resistive switching units 206 are located. The metal layer 2 may be made of metal such as Al or Cu. The source lines SL2 are perpendicular to the WLs in the spatial direction and parallel to the BLs in the spatial direction. Similarly, the source lines SL2 are electrically connected to the surface of the substrate 100 through contact plugs 220 and 222 in two contact holes, formed in an interlayer insulating film such as a silicon oxide film, and a bottom connecting platform 221, respectively. On the source lines SL2, the BLs are arranged through the metal layer 3 (M3).

FIG. 3C shows a cross-sectional view in the direction of C-C′. It can be seen that the source lines SL1 and the source lines SL2 are on different metal layers. The source lines SL1 and the source lines SL2 are coupled to storage units on different sides, and the projections of the source lines overlap with each other in the vertical direction. Shown in the figure is the connection portions between the source lines SL1 and source lines SL2 and the contact plugs, and the source lines SL1 and the source lines SL2 themselves are parallel to the BLs in the spatial direction. The source lines SL1 are electrically connected to the surface of the substrate 100 through the contact plugs 120, and the source lines SL2 are electrically connected to the surface of the substrate 100 through the contact plugs 220, the bottom connecting platforms 221, and the contact plugs 222.

FIG. 3D shows a cross-sectional view in the direction of D-D′. The source lines SL1 are located on the first interconnect layer and are formed through the metal layer 1 (M1); and the source lines SL2 are located on the second interconnect layer and are formed through the metal layer 2 (M2). The metal layer 2 (M2) is located above the metal layer 1 (M1). The source lines SL1 are coupled to the first resistive switching units 106, and the source lines SL2 are coupled to the second resistive switching units 206. What can be seen in the figure is the cross-sections of the source line SL1 and the source line SL2, of which the projections at least partially overlap with each other in the vertical direction, and the source line SL1 and the source line SL2 are parallel to the BLs in the spatial direction.

Another embodiment of the present invention is an electronic device using the integrated circuit in accordance with the mentioned embodiments. The integrated circuit includes a plurality of integrated circuit units and a plurality of source lines, where the plurality of source lines include first source lines and second source lines located on different layers, the first source lines and the second source lines are located on different interconnect layers, and the integrated circuit units are coupled to the first source lines or the second source lines.

According to the description, the descriptions of the reference terms “an embodiment”, “some embodiments”, “an example”, “a specific example”, “some examples,” and the like mean that specific features, structures, materials, or characteristics described in combination with the embodiment(s) or example(s) are included in at least one embodiment or example of the present invention. Besides, the specific features, structures, materials, or characteristics described may be combined in proper manners in any one or more embodiments or examples. In addition, a person skilled in the art may integrate or combine different embodiments or examples described in the description and features of different embodiments or examples as long as they are not contradictory to each other.

In addition, terms “first” and “second” are used merely for the purpose of description, and shall not be construed as indicating or implying relative importance or implying the quantity of indicated technical features. Therefore, features defined by “first” or “second” explicitly or implicitly indicate that at least one of the features is included. In the descriptions of the present invention, unless otherwise explicitly specified, “a plurality of” means two or more.

The above are only specific implementations of the present invention, but the scope of protection of the present invention is not limited to this. Any person skilled in the art can easily conceive of changes or substitutions within the technical scope disclosed in the present invention, which shall all fall within the scope of protection of the present invention. Therefore, the scope of protection of the present invention shall be subject to the scope of protection of the claims.

1-19. (canceled)

20. An integrated circuit, comprising:
a plurality of integrated circuit units and a plurality of source lines, wherein the plurality of source lines comprise first source lines and second source lines located on different layers, the first source lines and the second source lines are located on different interconnect layers, and the integrated circuit units are coupled to the first source lines or the second source lines.

21. The integrated circuit according to claim 20, wherein the integrated circuit is a memory, which comprises a plurality of storage units and a plurality of source lines, wherein the plurality of source lines comprise first source lines and second source lines located on different layers, the first source lines and the second source lines are located on different interconnect layers, and the storage units are coupled to the first source lines or the second source lines.

22. The integrated circuit according to claim 21, wherein the memory is a resistive random access memory, the storage units are a plurality of resistive memory cells arranged in row and column directions, each resistive memory cell comprises a resistive switching unit and a switch unit coupled to the resistive switching unit, the source lines comprise first source lines and second source lines, and the first source lines and the second source lines are located on different interconnect layers.

23. The integrated circuit according to claim 22, wherein the first source lines are located on a first interconnect layer, and the second source lines are located on a second interconnect layer above the first interconnect layer.

24. The integrated circuit according to claim 20, wherein a projection of at least one of the first source lines at least partially overlaps the projection of the corresponding second source line in a vertical direction.

25. The integrated circuit according to claim 24, wherein the first source line and the second source line, of which the projections at least partially overlap with each other in the vertical direction, are respectively coupled to the storage units located on different sides of the first source line and the second source line.

26. The integrated circuit according to claim 20, wherein the source lines are perpendicular to word lines in a spatial direction, and the source lines are parallel to bit lines in the spatial direction.

27. The integrated circuit according to claim 21, wherein the source lines are perpendicular to word lines in a spatial direction, and the source lines are parallel to bit lines in the spatial direction.

28. The integrated circuit according to claim 22, wherein the source lines are perpendicular to word lines in a spatial direction, and the source lines are parallel to bit lines in the spatial direction.

29. The integrated circuit according to claim 23, wherein the source lines are perpendicular to word lines in a spatial direction, and the source lines are parallel to bit lines in the spatial direction.

30. The integrated circuit according to claim 20, wherein the bit lines are located on a third interconnect layer above a second interconnect layer.

31. The integrated circuit according to claim 21, wherein the bit lines are located on a third interconnect layer above a second interconnect layer.

32. The integrated circuit according to claim 22, wherein the bit lines are located on a third interconnect layer above a second interconnect layer.

33. The integrated circuit according to claim 23, wherein bit lines are located on a third interconnect layer above the second interconnect layer.

34. The integrated circuit according to claim 20, wherein the first source lines are electrically connected to a substrate through N groups of contact plugs and N-1 groups of bottom connecting platforms, and the second source lines are electrically connected to the substrate through M groups of contact plugs and M-1 groups of bottom connecting platforms, wherein M is greater than N.

35. The integrated circuit according to claim 21, wherein the first source lines are electrically connected to a substrate through N groups of contact plugs and N-1 groups of bottom connecting platforms, and the second source lines are electrically connected to the substrate through M groups of contact plugs and M-1 groups of bottom connecting platforms, wherein M is greater than N.

36. The integrated circuit according to claim 22, wherein the first source lines are electrically connected to a substrate through N groups of contact plugs and N-1 groups of bottom connecting platforms, and the second source lines are electrically connected to the substrate through M groups of contact plugs and M-1 groups of bottom connecting platforms, wherein M is greater than N.

37. The integrated circuit according to claim 23, wherein the first source lines are electrically connected to a substrate through N groups of contact plugs and N-1 groups of bottom connecting platforms, and the second source lines are electrically connected to the substrate through M groups of contact plugs and M-1 groups of bottom connecting platforms, wherein M is greater than N.

38. An electronic device, comprising the integrated circuit according to claim 20.
